(19) United States
(12) Patent Application Publication
(10) Pub. No.: US 2026/0059787 A1
(43) Pub. Date: Feb. 26, 2026

(54) SEMICONDUCTOR DEVICE

(71) Applicant: Samsung Electronics Co., Ltd., Suwon-si (KR)

(72) Inventors: Seongpil CHANG, Suwon-si (KR); Deokjin JEON, Suwon-si (KR); Sungsu MOON, Suwon-si (KR); Sea Hoon LEE, Suwon-si (KR)

(73) Assignee: Samsung Electronics Co., Ltd., Suwon-si (KR)

(21) Appl. No.: 19/096,967

(22) Filed: Apr. 1, 2025

(30) Foreign Application Priority Data
Aug. 20, 2024 (KR) 10-2024-0111647

(51) Int. Cl. H10D 30/60; H10D 30/01

(52) U.S. Cl. CPC H10D 30/611; H10D 30/023

(57) ABSTRACT

A semiconductor device includes a substrate including an active region, a first gate electrode on the active region, a second gate electrode between the first gate electrode and the substrate, a first doped region on one side of the first gate electrode, a second doped region on an other side of the first gate electrode, a third doped region on one side of the first doped region, a fourth doped region on one side of the second doped region, and a plurality of wirings spaced apart from the first gate electrode in a first direction, the first gate electrode overlaps with each of the third doped region and the fourth doped region in the first direction, and each of the plurality of first wirings are spaced apart from each other in a second direction and the second direction within an area corresponding to a width of the first gate electrode.

### CROSS-REFERENCE TO RELATED APPLICATION

This application claims priority to and benefit of Korean Patent Application No. 10-2024-0111647, filed in the Korean Intellectual Property Office on Aug. 20, 2024, the entire contents of which are hereby incorporated by reference.

### BACKGROUND

Aspects of some example embodiments of the present disclosure relate to semiconductor devices.

Semiconductor devices are key components used to control or amplify electrical signals in electronic devices, and various types of semiconductor devices may be manufactured. For example, memory devices may be used primarily to store and retrieve data, while non-memory devices may be used to control or amplify electrical signals. Semiconductor devices are key components of electronic devices and play a vital role in a wide range of fields, including computers, communications equipment, and consumer electronics.

With the development of industry, demands on performance and functionality of electronic devices are increasing. Accordingly, high-performance characteristics of semiconductor devices are essential, and in order to meet these demands, various methods are being studied to improve not only the integration level of semiconductor devices but also their electrical characteristics and reliability.

### SUMMARY

The present disclosure has been proposed to solve or address the above technical problems, and aspects of some example embodiments of the present disclosure are to provide semiconductor devices with improved electrical characteristics and/or reliability.

A semiconductor device according to some example embodiments of the present disclosure for solving or addressing the above technical problems includes a substrate including an active region; a first gate electrode on the active region; a second gate electrode between the first gate electrode and the substrate in a first direction; a first doped region within the active region on one side of the first gate electrode; a second doped region within the active region on an other side of the first gate electrode; a third doped region on one side of the first doped region; a fourth doped region on one side of the second doped region; and a plurality of first wirings spaced apart from the first gate electrode in the first direction and extending in a second direction intersecting the first direction, wherein the first gate electrode overlaps with at least a part of each of the third doped region and the fourth doped region in the first direction, and wherein each of the plurality of first wirings is arranged spaced apart from each other in a third direction intersecting the first direction and the second direction, respectively, the plurality of first wirings are spaced apart from each other within an area corresponding to a width of the first gate electrode.

A semiconductor device according to some example embodiments of the present disclosure for solving or addressing the above technical problems includes a substrate including an active region, a gate electrode spaced apart in a first direction on the active region, a first doped region within the active region on one side of the gate electrode, a second doped region within the active region on an other side of the gate electrode, a third doped region on one side surface of the first doped region, a fourth doped region on one side surface of the second doped region, a gate contact on the gate electrode and extending in a first direction, a gate pad on the gate contact and be electrically connected to the gate electrode through the gate contact, and a plurality of wirings spaced apart from the gate pad in the first direction and extending in a second direction intersecting the first direction, wherein the gate pad may overlap with at least a part of each of the third doped region and the fourth doped region, and each of the plurality of wirings may be arranged spaced apart from each other in a third direction intersecting the first direction and the second direction, respectively, the plurality of wirings are spaced apart from each other within an area corresponding to a width of the gate pad.

A semiconductor device according to some example embodiments of the present disclosure for solving or addressing the above technical problems includes a substrate including an active region; a first gate electrode on the active region; a second gate electrode between the first gate electrode and the substrate; a gate dielectric including a first dielectric region between the first gate electrode and the substrate, and a second dielectric region between the second gate electrode and the substrate; a gate spacer on a side surface of the gate dielectric and the first gate electrode; a first doped region within the active region on one side of the first gate electrode; a second doped region within the active region on an other side of the first gate electrode; a third doped region on one side of the first doped region; a fourth doped region on one side surface of the second doped region; a plurality of wirings spaced apart from the first gate electrode in a first direction and extending in a second direction intersecting the first direction; and a liner layer on an upper surface of the first gate electrode and an outer surface of the gate spacer, wherein the first gate electrode overlaps with at least a part of each of the third doped region and the fourth doped region in the first direction, wherein each of the plurality of wirings is arranged spaced apart from each other in a third direction intersecting the first direction and the second direction, respectively, the plurality of wirings are spaced apart from each other within an area corresponding to a width of the first gate electrode, wherein the width of the first gate electrode is greater than a width of the second gate electrode, and wherein a thickness of the first dielectric region is greater than a thickness of the second dielectric region.

According to some example embodiments of the present disclosure, the performance of a semiconductor device may be improved by blocking or reducing the wiring influence of a peripheral circuit due to an extended gate electrode.

According to some example embodiments of the present disclosure, the wiring influence of the peripheral circuit may be blocked or reduced due to the extended gate electrode, thereby improving the wiring freedom of the peripheral circuit.

According to some embodiments of the present disclosure, the performance of a semiconductor device may be improved by blocking or reducing the wiring influence of a peripheral circuit due to an extended gate pad.

According to some embodiments of the present disclosure, the wiring influence of the peripheral circuit may be blocked or reduced due to the extended gate pad, thereby improving the wiring freedom of the peripheral circuit.

### BRIEF DESCRIPTION OF DRAWINGS

FIG. 1 is a plan view illustrating a semiconductor device according to some example embodiments of the present disclosure.

FIG. 2 is a cross-sectional view taken along line A-A of FIG. 1.

FIG. 3 is a view illustrating a semiconductor device according to some example embodiments of the present disclosure.

FIG. 4 is a view illustrating a semiconductor device according to some example embodiments of the present disclosure.

FIG. 5 is a plan view illustrating a semiconductor device according to some example embodiments of the present disclosure.

FIG. 6 is a cross-sectional view taken along line B-B of FIG. 5.

FIGS. 7 to 16 are views illustrating a method of manufacturing a semiconductor device according to some example embodiments of the present disclosure.

FIGS. 17 to 23 are views illustrating a method of manufacturing a semiconductor device according to some example embodiments of the present disclosure.

### DETAILED DESCRIPTION

Hereinafter, a semiconductor device and a manufacturing method thereof according to some example embodiments of the present disclosure will be described in detail with reference to drawings.

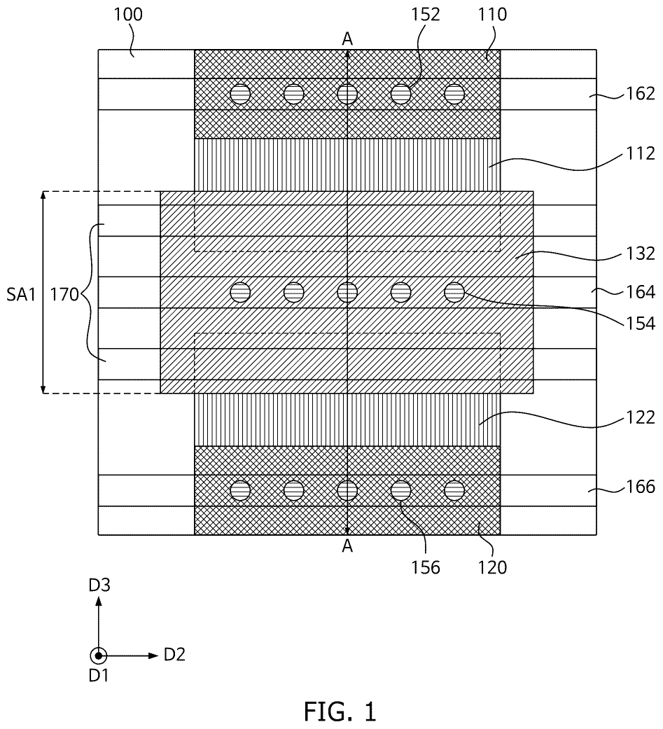

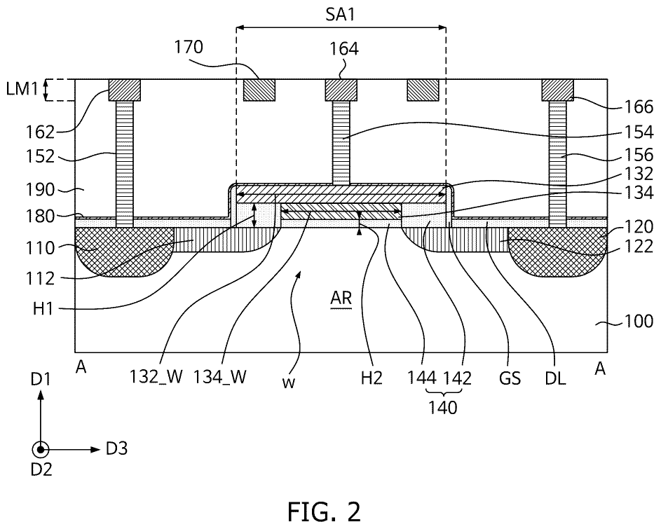

FIG. 1 is a plan view illustrating a semiconductor device according to some example embodiments of the present disclosure. FIG. 2 is a cross-sectional view taken along line A-A of FIG. 1.

Referring to FIGS. 1 and 2, a semiconductor device according to some example embodiments may include a substrate 100, gate electrodes 132 and 134, a gate dielectric 140, a source contact (152), a drain contact 156, a gate contact 154, a source pad 162, a drain pad 166, a gate pad 164, and a plurality of wirings 170.

Hereinafter, a direction perpendicular to the upper surface of the substrate 100 may be defined as the first direction (D1). Additionally, two directions parallel to the upper surface of the substrate 100 may be defined as the second direction (D2) and the third direction (D3), and each of the first direction (D1) to the third direction (D3) may intersect each other perpendicularly.

The substrate 100 may be any type of substrate capable of forming a field effect transistor. For example, the substrate 100 may be a semiconductor substrate. The substrate 100 may include, for example, at least one of a material having semiconductor properties (e.g., silicon (Si)), an insulating material (e.g., silicon oxide), and a semiconductor or conductor covered by an insulating material. However, the present disclosure is not limited to these examples.

An active region (AR) may be formed within the substrate 100. The active region (AR) may be defined by an isolation layer containing an insulating material. The isolation layer may be a shallow trench isolation layer. The insulating material included in the isolation layer may include silicon oxide, but the present disclosure is not limited to this example.

The active region (AR) may include a well region (W), a first doped region 110, a second doped region 120, a third doped region 112, and a fourth doped region 122. The well region (W) may be located below gate electrodes 132 and 134 within the active region (AR). The well region (W) may contain impurities of a first conductivity type. For example, the first conductivity type may be p-type or n-type. The P-type impurities may include any type of impurity that may generate holes as primary carriers. For example, the p-type impurities may include one or more elements selected from the group consisting of boron (B), aluminum (Al), gallium (Ga), indium (In), and/or thallium (TI), which are elements of group III of the periodic table. The n-type impurities may include any type of impurity that may generate electrons as primary carriers. For example, the n-type impurities may include one or more selected from the group consisting of nitrogen (N), phosphorus (P), arsenic (As), antimony (Sb), and/or bismuth (Bi), which are elements of group V of the periodic table.

The first doped region 110 and the second doped region 120 may be located within the active region (AR) adjacent to both sides of the gate electrodes 132 and 134. The first doped region 110 may be a source region. The second doped region 120 may be a drain region. The first doped region 110 may be located within the active region AR on one side of the gate electrodes 132 and 134. Additionally, the second doped region 120 may be located within the active region (AR) on the other side of the gate electrodes 132 and 134. The first doped region 110 and the second doped region 120 may be spaced apart from each other in a third direction (D3) with the well region (W) interposed therebetween. The first doped region 110 and the second doped region 120 may include impurities of a second conductivity type, which are different from the impurities included in the well region (W). The second conductivity type may be either p-type or n-type. For example, when the well region (W) includes n-type impurities, the first doped region 110 and the second doped region 120 may include p-type impurities. On the other hand, when the well region (W) includes p-type impurities, the first doped region 110 and the second doped region 120 may include n-type impurities.

The third doped region 112 and the fourth doped region 122 may be located within the active region (AR) adjacent to both sides of the gate electrodes 132 and 134. The third doped region 112 and the fourth doped region 122 may be lightly doped drain (LDD) regions. The third doped region 112 and the fourth doped region 122 may be located on both sides of the well region (W). For example, the third doped region 112 may be disposed on one side of the first doped region 110. As a specific example, the third doped region 112 may be disposed on one side of the first doped region 110 and may extend in a third direction (D3) toward the bottom of the gate electrodes 132 and 134. Additionally, the fourth doped region 122 may be disposed on one side of the second doped region 120. As a specific example, the fourth doped region 122 may be disposed on one side of the second doped region 120 and may extend in a third direction (D3) toward the bottom of the gate electrodes 132 and 134. The third doped region 112 and the fourth doped region 122 may be disposed spaced apart from each other in the third direction (D3) with the well region (W) interposed therebetween.

The third doped region 112 and the fourth doped region 122 may include impurities of the same second conductivity type as the first doped region 110 and the second doped region 120. However, the impurity concentrations of the third doped region 112 and the fourth doped region 122 may be lower than the impurity concentrations of the first doped region 110 and the second doped region 120.

The gate electrodes 132 and 134 may be disposed on the substrate 100. Specifically, the gate electrodes 132 and 134 may be disposed spaced apart from each other in the first direction (D1) on the active region (AR). That is to say, in some example embodiments, the gate electrodes 132 and 134 may be stacked on top of each other, e.g., overlap in a vertical direction, in the first direction (D1) on the active region. The gate electrodes 132 and 134 may overlap with the well region (W) in the first direction (D1). The gate electrodes 132 and 134 may have an upper surface and/or a bottom surface which are parallel to the second direction (D2) and the third direction (D3). In this case, the upper surface of the substrate 100 facing the bottom surface of the gate electrodes 132 and 134 may also be parallel to the second direction (D2) and the third direction (D3). That is, the semiconductor device of the present disclosure may be a planar type semiconductor device.

The gate electrodes 132 and 134 may include a first gate electrode 132 and a second gate electrode 134. The first gate electrode 132 may be disposed on the upper surface of the second gate electrode 134. The first gate electrode 132 may include a metal material. For example, the first gate electrode 132 may include at least one of Ti, TiN, Ta, TaN, W, WN, TiSiN, and/or WSIN. The second gate electrode 134 may include polysilicon. For example, the second gate electrode 134 may include polysilicon doped with impurities. The width (132_W) of the first gate electrode 132 may be larger than the width (134_W) of the second gate electrode 134. In some example embodiments, the first gate electrode 132 may overlap with at least a part of each of the third doped region 112 and the fourth doped region 122 in the first direction (D1). Here, the width (132_W) of the first gate electrode 132 and the width (134_W) of the second gate electrode 134 may represent the width of the first and second gate electrodes 132 and 134 in the third direction (D3).

The gate dielectric 140 may be disposed on the substrate 100. The gate dielectric 140 may be disposed between the gate electrodes 132 and 134 and the substrate 100. Specifically, the gate dielectric 140 may be disposed under the first gate electrode 132 and the second gate electrode 134.

In some example embodiments, the gate dielectric 140 may include a first dielectric region 142 between the first gate electrode 132 and the substrate 100 and a second dielectric region 144 between the second gate electrode 134 and the substrate 100. For example, due to the difference between the width (132_W) of the first gate electrode 132 and the width (134_W) of the second gate electrode 134, the gate dielectric 140 may be divided into a first dielectric region 142 disposed below the first gate electrode 132 and a second dielectric region 144 disposed below the second gate electrode 134. The first dielectric region 142 may be disposed spaced apart in the third direction (D3) with the second dielectric region 144 interposed therebetween. In this case, the thickness (H1) of the first dielectric region 142 may be greater than the thickness (H2) of the second dielectric region 144.

The gate dielectric 140 may include at least one of a silicon oxide film and a high dielectric constant material. The high dielectric constant material may be made of a material with a higher dielectric constant than the silicon oxide film. For example, the high dielectric constant material may include at least one of hafnium oxide (HfO), hafnium silicate (HfSiO), hafnium oxynitride (HfON), hafnium silicon oxynitride (HfSiON), lanthanum oxide (LaO), lanthanum aluminum oxide (LaAIO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), and/or lead scandium tantalum oxide (PbScTaO). In some example embodiments, the gate dielectric 140 may include a silicon oxide film disposed on the active region (AR), a hafnium oxide film disposed on the silicon oxide film, and at least one high dielectric constant material film disposed on the hafnium oxide film.

A gate spacer (GS) may be disposed on the side surface of the gate dielectric 140 and the first gate electrode 132. For example, the gate spacer (GS) may be disposed to cover both sides of the gate dielectric 140 and the first gate electrode 132, respectively. The inner surface of the gate spacer (GS) may be in contact with the outer surface of each of the first dielectric region 142 and the first gate electrode 132. The gate spacer (GS) may include the same material as the gate dielectric 140. However, the present disclosure is not limited to these examples.

A liner layer 180 may be disposed on the upper surface of the first gate electrode 132 and the outer surface of the gate spacer (GS). The liner layer 180 may be further disposed to extend to be parallel to the upper surface of the substrate 100 from the lower portion of the side surface of the gate spacer (GS). In this case, an insulating layer (DL) may be further disposed between the substrate 100 and a region extending to be parallel to the upper surface of the substrate 100 in the liner layer 180. That is to say, in some example embodiments, the insulating layer DL may extend in a direction extending parallel to the upper surface of the substrate 100, the insulating layer DL extending between the substrate 100 and the liner layer 180. The liner layer 180 may include silicon nitride (SiN), but the present disclosure is not limited thereto.

An interlayer insulating layer 190 may be formed on the liner layer 180. A source contact 152, a drain contact 156, a gate contact 154, a source pad 162, a drain pad 166, a gate pad 164, etc. may be formed inside the interlayer insulating layer 190. The interlayer insulating layer 190 may include the same material as the gate dielectric 140, but the present disclosure is not limited to this example.

The source contact 152 and the source pad 162 may be disposed on the first doped region 110. For example, the source contact 152 may extend in the first direction (D1) on the first doped region 110. The source pad 162 may be disposed on the source contact 152 and may extend in the second direction (D2). The source pad 162 may be electrically connected to the first doped region 110 through the source contact 152.

The drain contact 156 and the drain pad 166 may be disposed on the second doped region 120. For example, the drain contact 156 may extend in the first direction (D1) on the second doped region 120. The drain pad 166 may be disposed on the drain contact 156 and may extend in the second direction (D2). The drain pad 166 may be electrically connected to the second doped region 120 through the drain contact 156.

The gate contact 154 and the gate pad 164 may be disposed on the gate electrodes 132 and 134. For example, the gate contact 154 may extend in the first direction (D1) on the first gate electrode 132 and the second gate electrode 134. The gate pad 164 may be disposed on the gate contact 154 and may extend in the second direction (D2). The gate pad 164 may be electrically connected to the gate electrodes 132 and 134 through the gate contact 154.

A plurality of wirings 170 may be disposed spaced apart from each other in the first direction (D1) on the gate electrodes 132 and 134. The plurality of wirings 170 may extend in the second direction (D2). The plurality of wirings 170 may represent wirings of peripheral circuits that operate the semiconductor device, but the present disclosure is not limited to this example. In addition, although FIGS. 1 and 2 illustrate that one set of a plurality of wirings 170 is disposed on each side with the gate pad 164 therebetween, the present disclosure is not limited to this example. Two or more sets of the plurality of wirings 170 may be disposed on each side with the gate pad 164 therebetween.

In some example embodiments, the plurality of wirings 170 may be disposed within a first shielding area (SA1) by the first gate electrode (132). The first shielding area (SA) may represent an area corresponding to the width (132_W) of the first gate electrode 132. The first shielding area (SA) may include an overlapping region in the first direction (D1) between the first gate electrode 132 and the third doped region 112 and an overlapping region in the first direction (D1) between the first gate electrode 132 and the fourth doped region 122. That is, each of the plurality of wirings 170 may be arranged spaced apart from each other in the third direction (D3) within the first shielding area (SA), which is an area corresponding to the width (132_W) of the first gate electrode 132.

In some example embodiments, the plurality of wirings 170 may be disposed in a first vertical level (LM1). The plurality of wirings 170 may be disposed spaced apart from the first gate electrode 132 in the first direction (D1). In some example embodiments, the gate pad 164 may be disposed at substantially the same first vertical level (LM1) as the plurality of wirings 170. Additionally or alternatively, the source pad 162 may be disposed at substantially the same first vertical level (LM1) as the plurality of wirings 170. Additionally or alternatively, the drain pad 166 may be disposed at substantially the same first vertical level (LM1) as the plurality of wirings 170. Here, the vertical level (e.g., the first vertical level (LM1)) may represent the distance between the upper surface (or lower surface) of the substrate 100 and the upper surface (or lower surface or middle line) of each of the plurality of wirings 170. Additionally, the placement of several elements at the same vertical level may indicate that the upper surface (or lower surface, or middle line) of each of the elements is located at substantially the same vertical level.

The third and fourth doped regions in the substrate 100, e.g., LDD regions 112 and 122, may be accumulated or depleted by a voltage applied to wirings of a peripheral circuit (e.g., the plurality of wirings 170). As such, the resistance of the LDD regions 112 and 122 changes, which may be a factor in changing the characteristics of the semiconductor device (e.g., I_{off}, Iₒₙ, breakdown voltage). For example, when a semiconductor device is operating (e.g., Vg=29V), the resistance of the LDD regions 112 and 122 may increase due to the voltage of the wiring of the peripheral circuit not being applied. Accordingly, Iₒₙ may decrease. Additionally, when the semiconductor device is not operating (e.g., Vg=0V), the resistance of the LDD regions 112 and 122 may decrease due to the voltage (e.g., 29V) applied to the wiring of the peripheral circuit. Accordingly, I_{off} may increase. A decrease in Iₒₙ, an increase in I_{off}, and a decrease in breakdown voltage may be factors in the deterioration of semiconductor devices.

On the other hand, the wiring influence of the peripheral circuit may be blocked or reduced due to the extended gate electrode (e.g., the first gate electrode 132). For example, when a semiconductor device is operating (e.g., Vg=29V), the LDD regions 112 and 122 may be accumulated and the resistance may decrease by blocking or reducing the wiring influence of the peripheral circuit. Accordingly, Iₒₙ may increase. In addition, when the semiconductor device is not operating (e.g., Vg=0V), the LDD regions 112 and 122 may be depleted and the resistance may increase by blocking or reducing the wiring influence of the peripheral circuit. Accordingly, I_{off} may decrease. Additionally, the gate induced drain leakage-breakdown voltage (GIDL-BV) may increase through the above-described example embodiments. In addition, the wiring freedom of the peripheral circuit may be improved by blocking or reducing the wiring influence of the peripheral circuit due to the extended gate electrode (e.g., the first gate electrode 132).

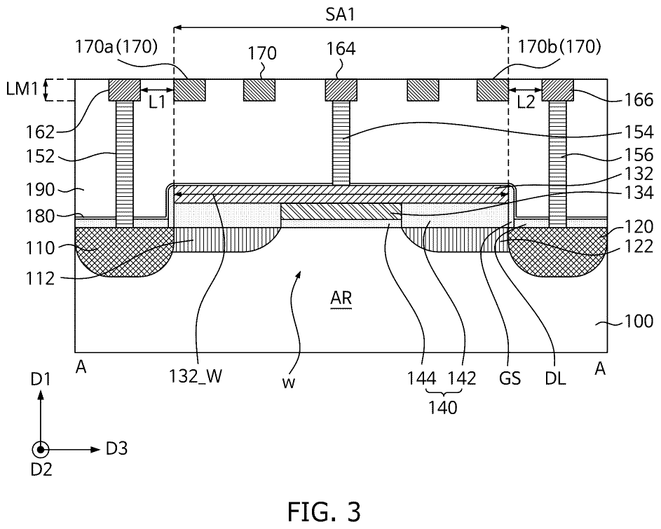

FIG. 3 is a view illustrating a semiconductor device according to some example embodiments of the present disclosure. The semiconductor device of FIG. 3 may be substantially the same as the semiconductor device described with reference to FIGS. 1 and 2, except that the first gate electrode 132 is further extended in the third direction (D3). For convenience of explanation, the explanation will focus on configurations different from those described in FIGS. 1 and 2.

Referring to FIG. 3, in some example embodiments, one end of the gate electrode 132 may be extended to be aligned with an edge of the first doped region 110. For example, one end of the gate electrode 132 may be disposed substantially aligned with the boundary between the first doped region 110 and the third doped region 112 in the first direction (D1). Similarly, the other end of the gate electrode 132 may be extended to be aligned with the edge of the second doped region 120. For example, the other end of the gate electrode 132 may be disposed substantially aligned with the boundary between the second doped region 120 and the fourth doped region 122 in the first direction (D1). That is to say, in some example embodiments, the gate electrode 132 may overlap the third doped region 112, for example all of the third doped region 112, and/or the fourth doped region 122, for example all of the fourth doped region 122, in the first direction.

In some example embodiments, the distance (L1) between the source pad 162 and the wiring 170a most adjacent to the source pad 162 among the plurality of wirings 170 may be 100 nanometers or greater. Additionally or alternatively, the distance (L2) between the drain pad 166 and the wiring 170b most adjacent to the drain pad 166 among the plurality of wirings 170 may be 100 nanometers or more. Although FIG. 3 illustrates that two sets of the plurality of wirings 170 are disposed on each side with the gate pad 164 therebetween, the present disclosure is not limited to this example. One set or three or more sets of the plurality of wirings 170 may be disposed on each side with the gate pad 164 therebetween.

In some example embodiments, the gate spacer (GS) may overlap with the first doped region 110 in the first direction (D1). Additionally or alternatively, the gate spacer (GS) may overlap with the second doped region 120 in the first direction (D1).

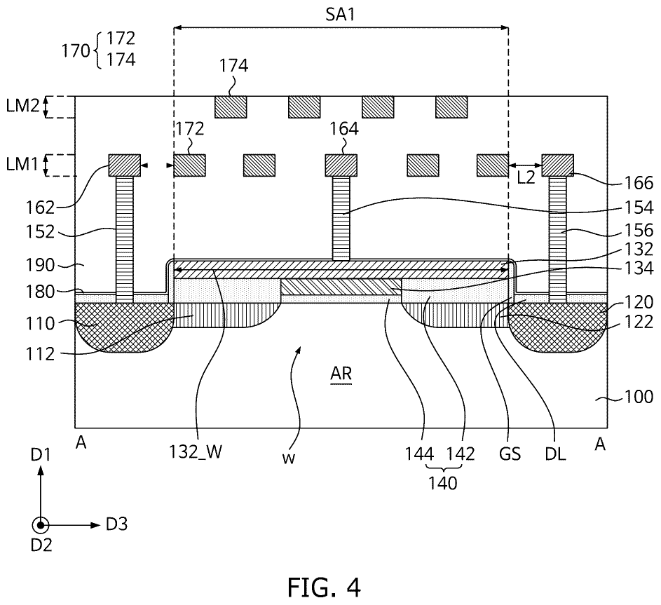

FIG. 4 is a view illustrating a semiconductor device according to some example embodiments of the present disclosure. The semiconductor device of FIG. 4 may be substantially the same as the semiconductor device described with reference to FIG. 3, except that a plurality of second wirings 174 are further disposed on a plurality of first wirings 172. For convenience of explanation, the explanation will focus on configurations different from those described in FIGS. 1 to 3.

Referring to FIG. 4, in some example embodiments, the plurality of wirings 170 may include a plurality of first wirings 172 and a plurality of second wirings 174. The plurality of first wirings 172 may be disposed at a first vertical level (LM1). The plurality of second wirings 174 may be disposed at a second vertical level (LM2) different from the first vertical level (LM1). The plurality of second wirings 174 may be disposed on the upper portion of the plurality of first wirings 172. The plurality of second wirings 174 may extend in the second direction (D2). In this case, each of the plurality of second wirings 174 may be arranged spaced apart from each other in the third direction (D3) within an area corresponding to the width (132_W) of the first gate electrode 132, that is, within the first shielding area (SA1) by the first gate electrode 132.

FIG. 4 illustrates some example embodiments in which both ends of the first gate electrode 132 are extended to be aligned with the edge of the first doped region 110 or the second doped region 120, respectively, but the present disclosure is not limited to this example. For example, in some example embodiments in which the plurality of second wirings 174 are further disposed on the plurality of first wirings 172, both ends of the plurality of first wirings 172 may overlap with the third doped region 112 or the fourth doped region 122 in the first direction (D1). In this case, the configuration related to the width of the plurality of first wirings 172 of the semiconductor device of FIG. 4 may be substantially the same as the semiconductor device described with reference to FIGS. 1 and 2.

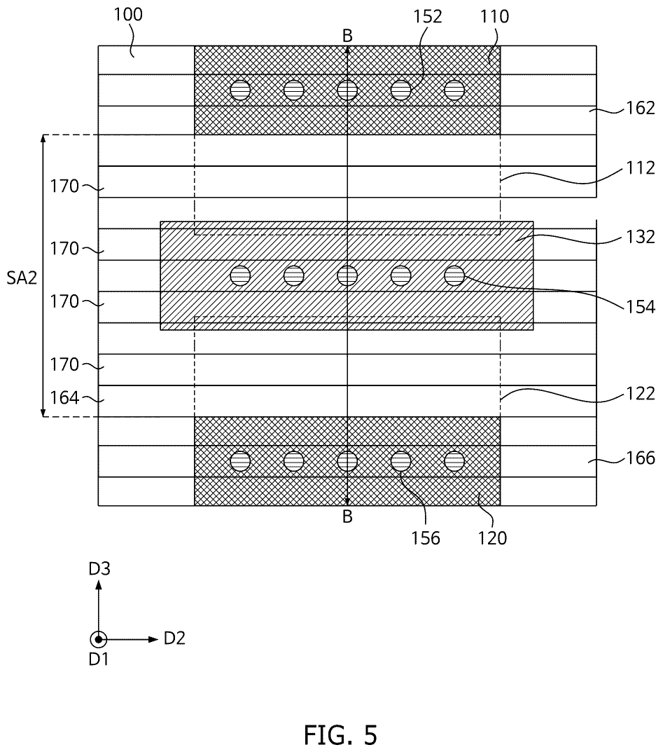

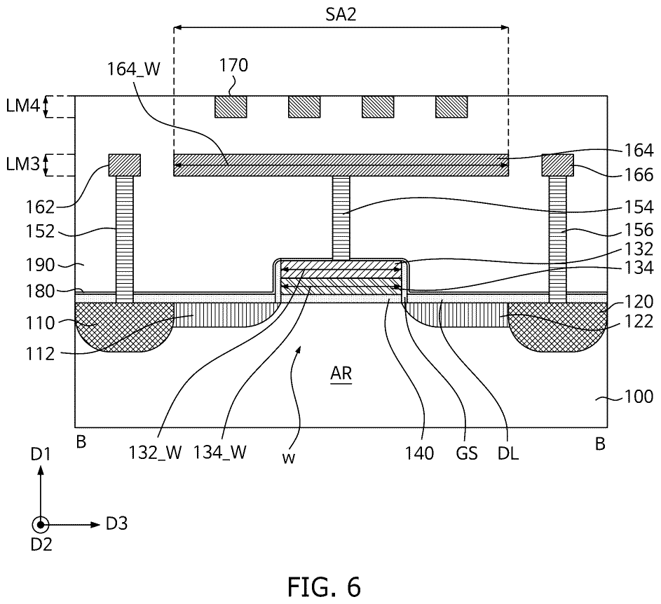

FIG. 5 is a plan view illustrating a semiconductor device according to some example embodiments of the present disclosure. FIG. 6 is a cross-sectional view taken along line B-B of FIG. 5. For convenience of explanation, the explanation will focus on configurations different from those described in FIGS. 1 to 4.

Referring to FIGS. 5 and 6, in some example embodiments, the gate pad 164 may overlap with at least a part of each of the third doped region 112 and the fourth doped region 122 in the first direction (D1). The width (164_W) of the gate pad 164 may be wider than the widths (132_W and 134_W) of the gate electrodes 132 and 134. Here, the width (164_W) of the gate pad 164 and the widths of the gate electrodes 132 and 134 may each represent a width in the third direction (D3). The gate pad 164 may have a plate shape extending in the second direction (D2) and the third direction (D3).

In some example embodiments, the gate pad 164 may be disposed at a third vertical level (LM3). The gate pad 164 may be disposed at the same vertical level as the source pad 162 and/or the drain pad 166. For example, the gate pad 164 may be disposed at a third vertical level (LM3) substantially the same as the source pad 162. Additionally or alternatively, the gate pad 164 may be disposed at a third vertical level (LM3) substantially the same as the drain pad 166.

In some example embodiments, the plurality of wirings 170 may be disposed spaced apart from the gate pad 164 in the first direction (D1). For example, the plurality of wirings 170 may be disposed in a fourth vertical level (LM4) that is different from the third vertical level (LM3). The fourth vertical level (LM4) may be located above the third vertical level (LM3). Here, the vertical level (e.g., the third and fourth vertical levels (LM3 and LM4)) may represent the distance between the upper surface (or lower surface) of the substrate 100 and the upper surface (or lower surface or middle line) of each of the plurality of wirings 170. Additionally, the placement of several elements at the same vertical level may indicate that the upper surface (or lower surface, or middle line) of each of the elements is located at substantially the same vertical level.

In some example embodiments, the plurality of wirings 170 may be disposed within a second shielding area (SA2) by the gate pad 164. In this case, the second shielding area (SA2) may represent an area corresponding to the width (164_W) of the gate pad 164. The second shielding area (SA2) may include an overlapping region in the first direction (D1) between the gate pad 164 and the third doped region 112 and an overlapping region in the first direction (D1) between the gate pad 164 and the fourth doped region 122. That is, each of the plurality of wirings 170 may be arranged spaced apart from each other in the third direction (D3) within the second shielding area (SA2), which is an area corresponding to the width (164_W) of the gate pad 164.

The extended gate pad 164 may block or reduce the wiring influence of the peripheral circuit. This may result in an increase in lon when the semiconductor device is operating (e.g., Vg=29 V) and a decrease in I_{off} when the semiconductor device is not operating (e.g., Vg=0 V). Additionally, there is an effect of increasing the gate induced drain leakage-breakdown voltage (GIDL-BV). In addition, the wiring freedom of the peripheral circuit may be improved by blocking or reducing the wiring influence of the peripheral circuit due to the extended gate pad 164.

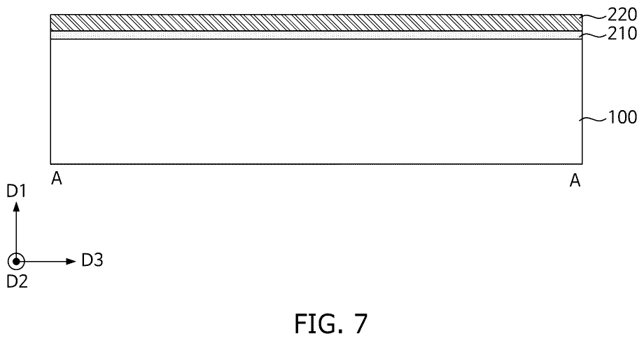

FIGS. 7 to 16 are views illustrating a method of manufacturing a semiconductor device according to some example embodiments of the present disclosure. FIGS. 7 to 16 describe a method for manufacturing the semiconductor device described with reference to FIGS. 1 and 2. FIGS. 7 to 16 may be drawings corresponding to cross-sectional views taken along line A-A of FIG. 1 or drawings related thereto.

Referring to FIG. 7, a first preliminary gate dielectric 210 and a first preliminary gate electrode 220 may be formed on a substrate 100. The substrate 100 may include a well region (e.g., a well region (W) of FIG. 2) having impurity ions of the first conductivity type. Each of the first preliminary gate dielectric 210 and the first preliminary gate electrode 220 may be sequentially laminated on the substrate 100. For example, the first preliminary gate dielectric 210 may be formed using an atomic layer deposition (ALD) method or a chemical oxide film formation method. Additionally, the first preliminary gate electrode 220 may be formed using an ALD, metal organic ALD (MOALD), chemical vapor deposition (CVD), metal organic CVD (MOCVD), or physical vapor deposition (PVD) process. However, the present disclosure is not limited to these examples. The first preliminary gate dielectric 210 may include the same material as the gate dielectric 140 described with reference to FIGS. 1 and 2. The first preliminary gate electrode 220 may include the same material as the second gate electrode 134 described with reference to FIGS. 1 and 2.

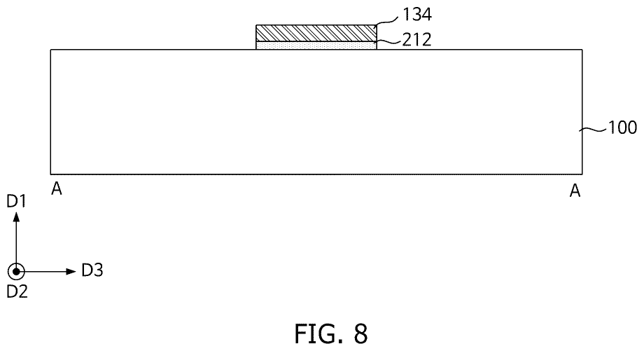

Referring to FIG. 8, the patterned first preliminary gate dielectric 212 and the second gate electrode 134 may be formed through patterning. The second gate electrode 134 may be disposed on the patterned first preliminary gate dielectric 212. The patterned first preliminary gate dielectric 212 may correspond to the second dielectric region 144 of the gate dielectric 140 described with reference to FIGS. 1 and 2.

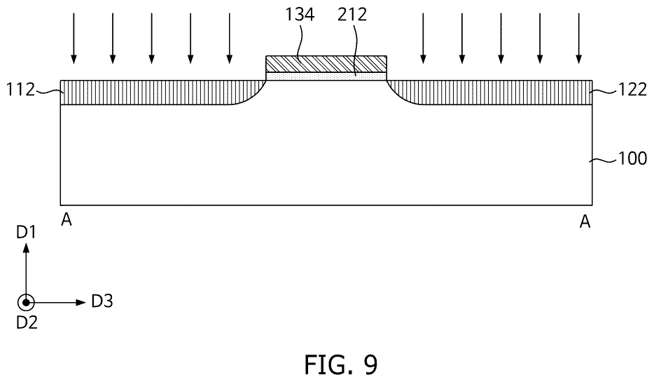

Referring to FIG. 9, a third doped region 112 and a fourth doped region 122 may be formed. For example, the third doped region 112 and the fourth doped region 122 may be formed in the substrate 100 through an LDD ion implantation process. The third doped region 112 and the fourth doped region 122 may be formed inside the substrate 100 while being spaced apart in the third direction (D3) with the patterned first preliminary gate dielectric 212 and the second gate electrode 134 interposed therebetween. The third doped region 112 and the fourth doped region 122 may be formed to be doped with impurity ions of a second conductivity type different from the well region of the substrate 100.

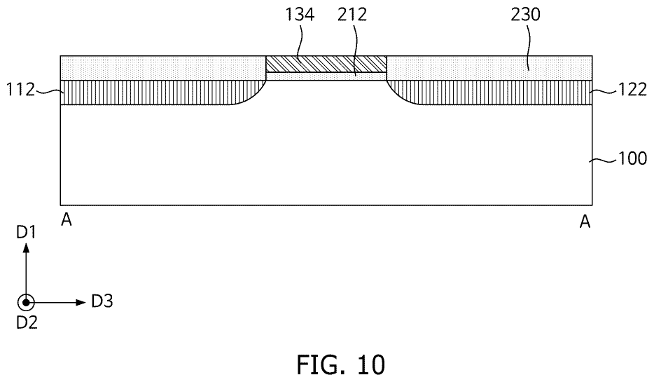

Referring to FIG. 10, a second preliminary gate dielectric 230 may be formed on the substrate 100. For example, the second preliminary gate dielectric 230 may be formed to cover both side surfaces of the patterned first preliminary gate dielectric 212 and the second gate electrode 134 and the upper surface of the substrate 100. The upper surface of the second preliminary gate dielectric 230 and the upper surface of the second gate electrode 134 may be disposed on the same plane.

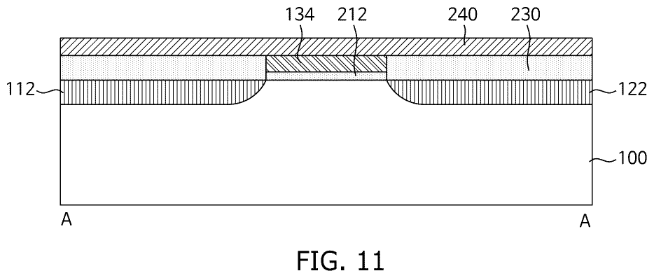

Referring to FIG. 11, a second preliminary gate electrode 240 may be formed. The second preliminary gate electrode 240 may be formed on the upper surface of the second gate electrode 134 and the second preliminary gate dielectric 230. Additionally, the second preliminary gate electrode 240 may be formed using an ALD, metal organic ALD (MOALD), chemical vapor deposition (CVD), metal organic CVD (MOCVD), or physical vapor deposition (PVD) process. However, the present disclosure is not limited to these examples.

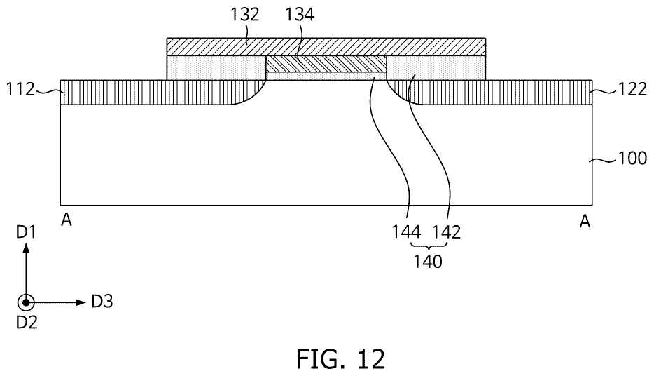

Referring to FIG. 12, a second preliminary gate electrode 240 may be patterned to form a first gate electrode 132 having a wider width than the second gate electrode 134. The first dielectric region 142 of the gate dielectric 140 may be formed by patterning the second preliminary gate dielectric 230 together with the second preliminary gate electrode 240. Due to the difference in width in the third direction (D3) between the first gate electrode 132 and the second gate electrode 134, the gate dielectric 140 may include a first dielectric region 142 and a second dielectric region 144. The first dielectric region 142 may represent a partial region of the gate dielectric 140 disposed between the first gate electrode 132 and the substrate 100. Further, the second dielectric region 144 may represent a partial region of the gate dielectric 140 disposed between the second gate electrode 134 and the substrate 100.

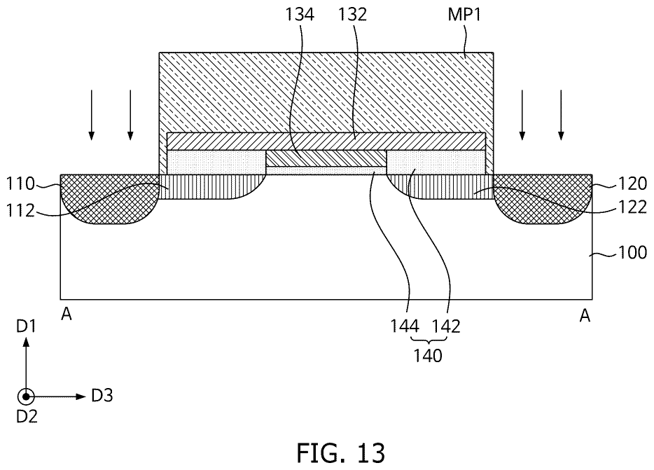

Referring to FIG. 13, a first doped region 110 and a second doped region 120 may be formed inside the substrate 100. For example, an ion implantation process may be performed using the first mask pattern (MP1) as an ion implantation mask. The first mask pattern (MP1) may be formed to cover the upper surface and the side surface of the first gate electrode 132 and the side surface of the gate dielectric 140, and an ion implantation process may be performed to form a first doped region 110 and a second doped region 120 through openings of the first mask pattern (MP1) formed on both sides of the first gate electrode 132.

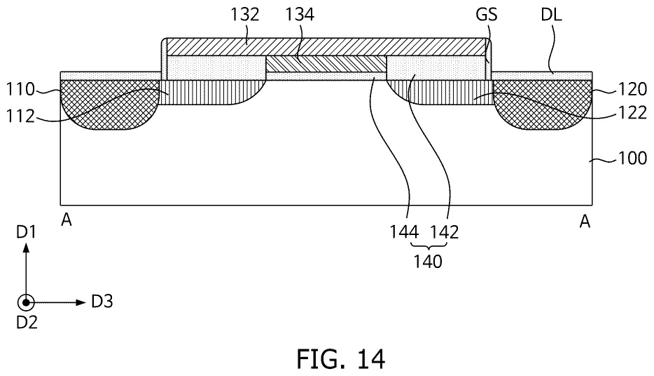

Referring to FIG. 14, a gate spacer (GS) and an insulating layer (DL) may be further formed. For example, a gate spacer (GS) may be formed on both side surfaces of the gate dielectric 140 and the first gate electrode 132. An insulating layer (DL) may be disposed on the upper surface of the substrate 100 while being spaced apart in the third direction (D3) with the gate electrodes 132 and 134 and the gate dielectric 140 interposed therebetween. Referring to FIG. 13 and FIG. 14, it is illustrated that a gate spacer (GS) and an insulating layer (DL) are formed after a first doped region 110 and a second doped region 120 are formed inside a substrate 100, but the present disclosure is not limited to this example. For example, after the gate spacer (GS) and the insulating layer (DL) are formed, the first doped region 110 and the second doped region 120 may be formed.

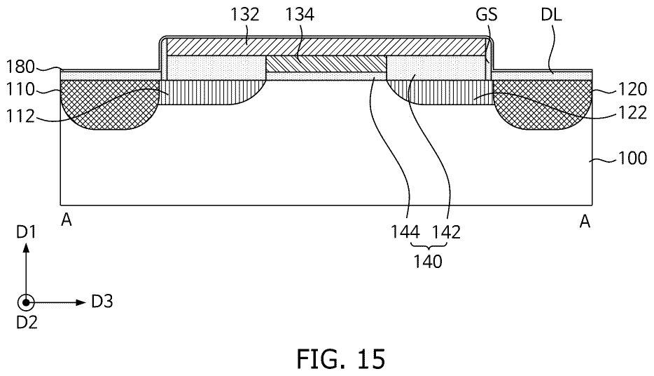

Referring to FIG. 15, a liner layer 180 may be further formed. For example, the liner layer 180 may be disposed on the upper surface of the first gate electrode 132, the outer surface of the gate spacer (GS), and the upper surface of the insulating layer (DL).

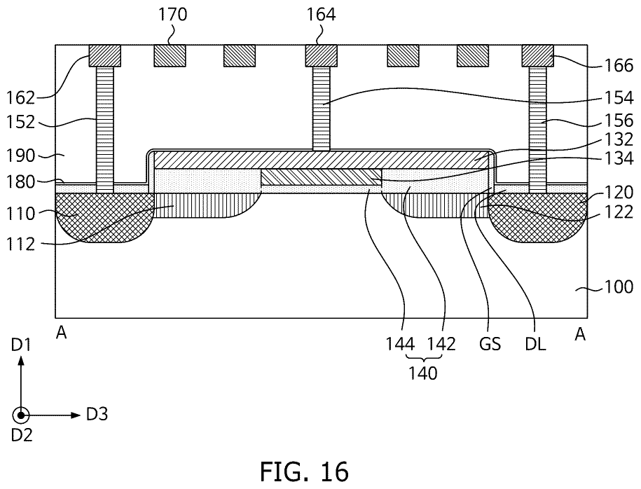

Referring to FIG. 16, an interlayer insulating layer 190 may be formed on the liner layer 180. A source contact 152, a drain contact 156, a gate contact 154, a source pad 162, a drain pad 166, and a gate pad 164 may be formed inside the interlayer insulating layer 190. The source contact 152 may extend in the first direction (D1) on the first doped region 110. The source pad 162 may be formed on the source contact 152. The drain contact 156 may be formed on the second doped region 120. The drain pad 166 may be formed on the drain contact 156. The gate contact 154 may be formed on the gate electrodes 132 and 134. The gate pad 164 may be formed on the gate contact 154.

A plurality of wirings 170 may be further formed inside the interlayer insulating layer 190. In this case, each of the plurality of wirings 170 may be formed within an area (e.g., the first shielding area (SA1) of FIGS. 1 to 4) that overlaps with the first gate electrode 132 in the first direction (D1). The plurality of wirings 170 may be formed between the source pad 162 and the gate pad 164 or between the drain pad 166 and the gate pad 164. In some example embodiments, the plurality of wirings 170 may be formed on substantially the same vertical level as at least one of the source pad 162, the drain pad 166, and the gate pad 164.

A semiconductor device described with reference to FIGS. 1 to 4 may be provided through a method identical or similar to the manufacturing method described above.

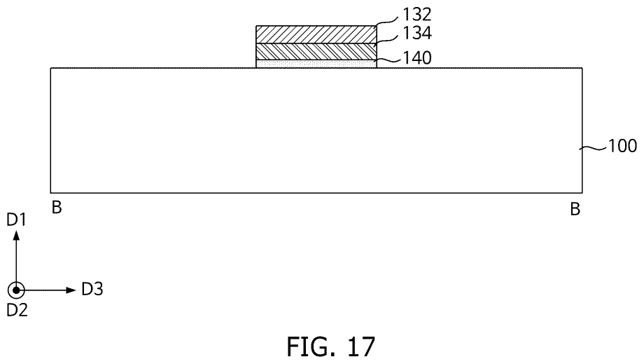

FIGS. 17 to 23 are views illustrating a method of manufacturing a semiconductor device according to some example embodiments of the present disclosure. FIGS. 17 to 23 describe a method for manufacturing the semiconductor device described with reference to FIGS. 5 and 6. FIGS. 17 to 23 may be drawings corresponding to cross-sectional views taken along line B-B of FIG. 5 or drawings related thereto.

Referring to FIG. 17, a first gate electrode 132, a second gate electrode 134, and a gate dielectric 140 may be formed on a substrate 100. The substrate 100 may include a well region (e.g., a well region (W) of FIG. 6) having impurity ions of the first conductivity type. The widths of the first gate electrode 132, the second gate electrode 134, and the gate dielectric 140 in the third direction (D3) may be substantially the same.

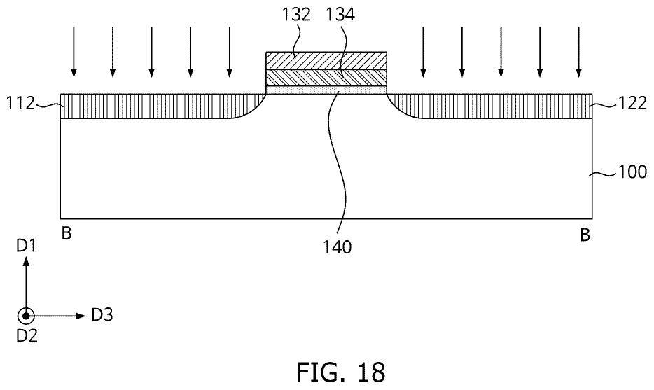

Referring to FIG. 18, a third doped region 112 and a fourth doped region 122 may be formed. For example, the third doped region 112 and the fourth doped region 122 may be formed in the substrate 100 through an LDD ion implantation process. The third doped region 112 and the fourth doped region 122 may be formed inside the substrate 100 spaced apart in the third direction (D3) with the first gate electrode 132 interposed therebetween. The third doped region 112 and the fourth doped region 122 may be formed to have impurity ions of a second conductivity type different from the well region of the substrate 100.

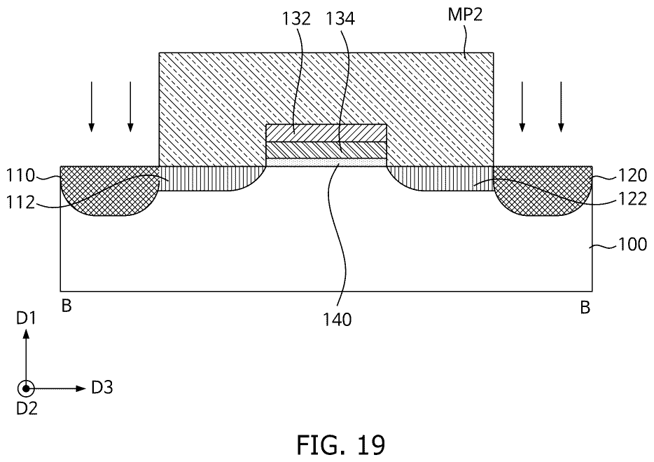

Referring to FIG. 19, a first doped region 110 and a second doped region 120 may be formed inside the substrate 100. For example, an ion implantation process may be performed using the second mask pattern (MP1) as an ion implantation mask. The second mask pattern (MP2) may be formed to cover the upper surface and the side surface of the first gate electrode 132, the side surface of the second gate electrode 134, and the side surface of the gate dielectric 140, and an ion implantation process may be performed to form the first doped region 110 and the second doped region 120 through the openings of the first mask pattern (MP1) formed on both sides of the first gate electrode 132.

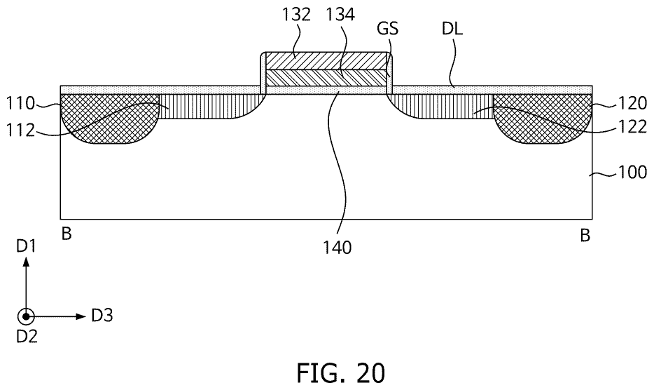

Referring to FIG. 20, a gate spacer (GS) and an insulating layer (DL) may be further formed. For example, the gate spacer (GS) may be formed on both side surfaces of the gate dielectrics 132 and 134 and the first gate electrode 132. An insulating layer (DL) may be disposed on the upper surface of the substrate 100 while being spaced apart in the third direction (D3) with the gate electrodes 132 and 134 and the gate dielectric 140 interposed therebetween. Referring to FIG. 19 and FIG. 20, it is illustrated that a gate spacer (GS) and an insulating layer (DL) are formed after a first doped region 110 and a second doped region 120 are formed inside a substrate 100, but the present disclosure is not limited to this example. For example, after the gate spacer (GS) and the insulating layer (DL) are formed, the first doped region 110 and the second doped region 120 may be formed.

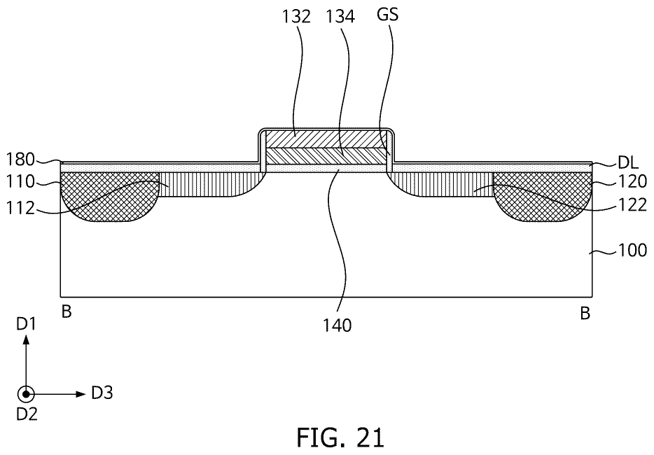

Referring to FIG. 21, a liner layer 180 may be further formed. For example, the liner layer 180 may be disposed on the upper surface of the first gate electrode 132, the outer surface of the gate spacer (GS), and the upper surface of the insulating layer (DL).

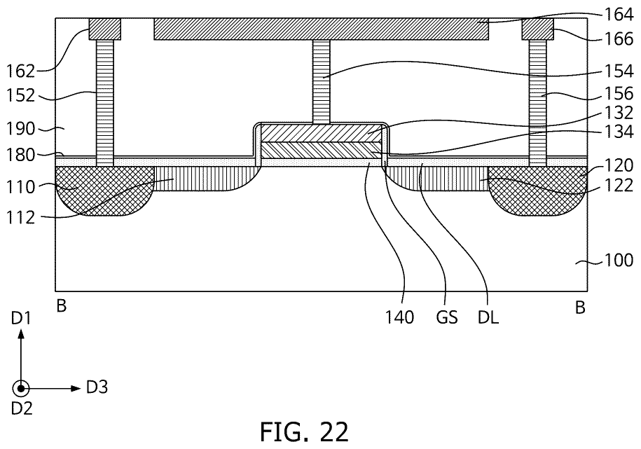

Referring to FIG. 22, an interlayer insulating layer 190 may be formed on the liner layer 180. A source contact 152, a drain contact 156, a gate contact 154, a source pad 162, a drain pad 166, and a gate pad 164 may be formed inside the interlayer insulating layer 190. The source contact 152 may extend in the first direction (D1) on the first doped region 110. The source pad 162 may be formed on the source contact 152. The drain contact 156 may be formed on the second doped region 120. The drain pad 166 may be formed on the drain contact 156. The gate contact 154 may be formed on the gate electrodes 132 and 134. The gate pad 164 may be formed on the gate contact 154. The width of the gate contact 154 in the third direction (D3) may be larger than the width of the gate electrodes 132 and 134. The gate pad 164 may be formed to overlap with at least a part of each of the third doped region 112 and the fourth doped region 122 in the first direction (D1). In some example embodiments, each of the source pad 162, the drain pad 166, and the gate pad 164 may be formed on substantially the same vertical level.

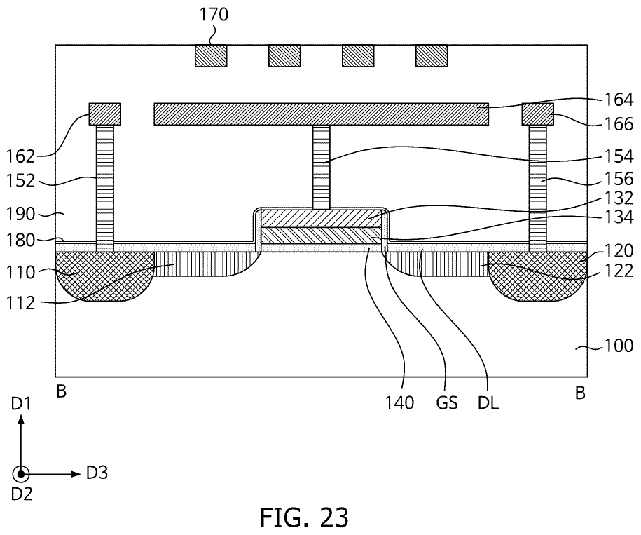

Referring to FIG. 23, a plurality of wirings 170 may be further formed inside the interlayer insulating layer 190. In this case, an interlayer insulating layer 190 may be additionally formed on the source pad 162, the drain pad 166, and the gate pad 164. Each of the plurality of wirings 170 may be formed spaced apart from the gate pad 164 in the first direction (D1). For example, each of the plurality of wirings 170 may be disposed on the upper portion of the gate pad 164 and formed to overlap with the gate pad 164 in the first direction (D1). As a specific example, each of the plurality of wirings 170 may be formed within an area (e.g., the second shielding area (SA2) of FIGS. 5 and 6) that overlaps with the gate pad 164 in the first direction (D1).

A semiconductor device described with reference to FIGS. 5 and 6 may be provided through a method identical or similar to the manufacturing method described above.

While the present inventive concepts have been particularly shown and described with reference to some example embodiments thereof, it is to be understood that the present inventive is not limited to the disclosed example embodiments, and various changes and modifications may be made without departing from the technical idea of the present inventive concepts and the scope of the appended claims.

What is claimed is:

1. A semiconductor device comprising:
a substrate including an active region;
a first gate electrode on the active region;
a second gate electrode between the first gate electrode and the substrate in a first direction;
a first doped region within the active region on one side of the first gate electrode;
a second doped region within the active region on an other side of the first gate electrode;
a third doped region on one side of the first doped region;
a fourth doped region on one side of the second doped region; and
a plurality of first wirings spaced apart from the first gate electrode in the first direction and extending in a second direction intersecting the first direction,
wherein the first gate electrode overlaps with at least a part of each of the third doped region and the fourth doped region in the first direction, and
wherein each of the plurality of first wirings is arranged spaced apart from each other in a third direction intersecting the first direction and the second direction, respectively, the plurality of first wirings are spaced apart from each other within an area corresponding to a width of the first gate electrode.

2. The semiconductor device as claimed in claim 1, wherein each of the plurality of first wirings overlap the first gate electrode in the first direction.

3. The semiconductor device as claimed in claim 1, further comprising:
a gate contact on the first gate electrode and extending in the first direction; and
a gate pad on the gate contact and electrically connected to the first gate electrode through the gate contact,
wherein the gate pad is at a same first vertical level as the plurality of first wirings.

4. The semiconductor device as claimed in claim 3, further comprising:
a plurality of second wirings at a second vertical level different from the first vertical level,
wherein each of the plurality of second wirings is spaced apart from each other in the third direction within the area corresponding to the width of the first gate electrode.

5. The semiconductor device as claimed in claim 3, further comprising:
a source contact on the first doped region and extending in the first direction;
a source pad on the source contact and electrically connected to the first doped region through the source contact;
a drain contact on the second doped region and extending in the first direction; and
a drain pad on the drain contact and electrically connected to the second doped region through the drain contact,
wherein at least one of the source pad and the drain pad is at the same first vertical level as the gate pad and the plurality of first wirings.

6. The semiconductor device as claimed in claim 1, wherein the width of the first gate electrode is greater than a width of the second gate electrode.

7. The semiconductor device as claimed in claim 1, further comprising:
a gate dielectric including a first dielectric region between the first gate electrode and the substrate, and a second dielectric region between the second gate electrode and the substrate,
wherein a thickness of the first dielectric region is greater than a thickness of the second dielectric region.

8. The semiconductor device as claimed in claim 1, wherein the first gate electrode includes a metal material, and the second gate electrode includes polysilicon.

9. The semiconductor device as claimed in claim 7, further comprising:
a gate spacer on a side surface of the first gate electrode and a side surface of the gate dielectric.

10. The semiconductor device as claimed in claim 9, further comprising:
a liner layer on an upper surface of the first gate electrode and an outer surface of the gate spacer.

11. The semiconductor device as claimed in claim 1, wherein one end of the first gate electrode is extended to be aligned with an edge of the first doped region, and
wherein an other end of the first gate electrode is extended to be aligned with an edge of the second doped region.

12. A semiconductor device comprising:
a substrate including an active region;
a gate electrode on the active region;
a first doped region within the active region on one side of the gate electrode;
a second doped region within the active region on an other side of the gate electrode;
a third doped region on one side surface of the first doped region;
a fourth doped region on one side surface of the second doped region;
a gate contact on the gate electrode and extending in a first direction;
a gate pad on the gate contact and electrically connected to the gate electrode through the gate contact; and
a plurality of wirings spaced apart from the gate pad in the first direction and extending in a second direction intersecting the first direction,
wherein the gate pad overlaps with at least a part of each of the third doped region and the fourth doped region, and
wherein each of the plurality of wirings is arranged spaced apart from each other in a third direction intersecting the first direction and the second direction, respectively, the plurality of wirings are spaced apart from each other within an area corresponding to a width of the gate pad.

13. The semiconductor device as claimed in claim 12, further comprising:
a source contact on the first doped region and extending in the first direction;
a source pad on the source contact and electrically connected to the first doped region through the source contact;
a drain contact on the second doped region and extending in the first direction; and
a drain pad on the drain contact and electrically connected to the second doped region through the drain contact,
wherein at least one of the source pad or the drain pad is at a same vertical level as the gate pad.

14. The semiconductor device as claimed in claim 12, wherein the width of the gate pad is greater than a width of the gate electrode.

15. The semiconductor device as claimed in claim 12, further comprising:
a gate dielectric between the gate electrode and the substrate.

16. The semiconductor device as claimed in claim 15, further comprising:
a gate spacer on a side surface of the gate electrode and a side surface of the gate dielectric.

17. The semiconductor device as claimed in claim 16, further comprising:
a liner layer on an upper surface of the gate electrode and an outer surface of the gate spacer.

18. The semiconductor device as claimed in claim 12, wherein the gate electrode includes a first gate electrode including a metal material and a second gate electrode including polysilicon.

19. The semiconductor device as claimed in claim 12, wherein one end of the gate pad is extended to be aligned with an edge of the first doped region, and
wherein an other end of the gate pad is extended to be aligned with an edge of the second doped region.

20. A semiconductor device comprising:
a substrate including an active region;
a first gate electrode on the active region;
a second gate electrode between the first gate electrode and the substrate;
a gate dielectric including a first dielectric region between the first gate electrode and the substrate, and a second dielectric region between the second gate electrode and the substrate;
a gate spacer on a side surface of the gate dielectric and the first gate electrode;
a first doped region within the active region on one side of the first gate electrode;
a second doped region within the active region on an other side of the first gate electrode;
a third doped region on one side of the first doped region;
a fourth doped region on one side surface of the second doped region;
a plurality of wirings spaced apart from the first gate electrode in a first direction and extending in a second direction intersecting the first direction; and
a liner layer on an upper surface of the first gate electrode and an outer surface of the gate spacer,
wherein the first gate electrode overlaps with at least a part of each of the third doped region and the fourth doped region in the first direction,
wherein each of the plurality of wirings is arranged spaced apart from each other in a third direction intersecting the first direction and the second direction, respectively, the plurality of wirings are spaced apart from each other within an area corresponding to a width of the first gate electrode,
wherein the width of the first gate electrode is greater than a width of the second gate electrode, and
wherein a thickness of the first dielectric region is greater than a thickness of the second dielectric region.
